(19) United States
(12) Patent Application Publication
(10) Pub. No.: US 2026/0223482 A1
(43) Pub. Date: Jul. 30, 2026

(54) METHODS FOR CONTROLLING PASSIVATING CONTACT THICKNESS IN BACKSIDE CONTACT SOLAR CELLS

(71) Applicant: Maxeon Solar Pte. Ltd., Singapore (SG)

(72) Inventors: Caroline Anderson, Evergreen, CO (US); David D. Smith, Campbell, CA (US)

(73) Assignee: Maxeon Solar Pte. Ltd., Singapore (SG)

(21) Appl. No.: 19/036,704

(22) Filed: Jan. 24, 2025

(51) Int. Cl. H10F 77/30; H10F 71/00

(52) U.S. Cl. CPC H10F 77/311; H10F 71/1221; H10F 71/129

(57) ABSTRACT

A method of forming a solar cell is disclosed. The method includes forming a multilayered stack of materials on a substrate, forming a plurality of openings in the top layer of the multilayered stack of materials, forming a plurality of dielectric regions that are aligned to the plurality of openings on a polysilicon layer of the multilayered stack of materials, and forming a plurality of trenches around the plurality of dielectric regions to form a plurality of first polysilicon regions and one or more second polysilicon regions. The method further includes, after forming the plurality of trenches, forming a first doped material on exposed surfaces of remaining portions of the multilayered stack of materials, using the first doped material to cause the plurality of first polysilicon regions to have a doping type that corresponds to the doping type of the first doped material, and using a second doped material to cause the one or more second polysilicon regions to have a doping type that corresponds to the doping type of the second doped material.

### TECHNICAL FIELD

Embodiments of the disclosure pertain to backside contact solar cell contacts, and in particular, methods for controlling the passivating contact coverage area fraction.

### BACKGROUND

Solar cells are devices for converting solar radiation to electrical energy. They may be fabricated on a semiconductor wafer using semiconductor processing technology. A solar cell may include p-type and n-type doped regions. Solar radiation impinging on the solar cell creates electrons and holes that migrate to the doped regions and create voltage differentials between them that generate electrical current. In a backside contact solar cell, both doped regions and metal contacts are located on the backside of the solar cell. The metal contacts allow external electric circuits to be coupled to and powered by the solar cell. Efficiency is an important characteristic of solar cells that is related to their capacity to generate power. However, there are significant challenges related to the design and fabrication of solar cells with improved efficiency.

### BRIEF DESCRIPTION OF THE DRAWINGS

FIG. 1A illustrates an exemplary operating environment of photovoltaic modules having solar cells whose passivating contacts have a coverage area fraction that has been controlled according to one embodiment.

FIG. 1B shows a cross-section of a portion of a solar cell whose passivating contacts have a coverage area fraction that has been controlled according to one embodiment.

FIG. 1C illustrates the positioning of a plurality of trenches around a plurality of polysilicon structures in the solar cell of FIG. 1B according to one embodiment.

FIG. 1D illustrates an elongated trench structure according to one embodiment.

FIGS. 2A-2K are illustrations of cross-sections of a multilayered semiconductor structure during fabrication of a solar cell according to one embodiment.

FIGS. 3A-3I are illustrations of cross-sections of a multilayered semiconductor structure during fabrication of a solar cell according to one embodiment.

### DESCRIPTION OF THE EMBODIMENTS

Methods for controlling passivating contact coverage area fraction of backside contact solar cells are described. It should be appreciated that although embodiments are described herein with reference to example methods for controlling coverage area fraction of passivating contacts of a solar cell, the disclosure is more generally applicable to methods for controlling coverage area fraction of passivating contacts of a solar cell as well as other type methods for controlling coverage area fraction of passivating contacts of a solar cell. In the following description, numerous specific details are set forth, in order to provide a thorough understanding of embodiments of the present disclosure. It will be apparent to one skilled in the art that embodiments of the present disclosure may be practiced without these specific details. In other instances, well-known features, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

As used herein, the term “passivating contact” is intended to refer to a polysilicon on dielectric contact.

As used herein, the term “defect precursor” is intended to refer to any feature in the fabrication process, that if not mitigated, will result in the formation of a physical defect downstream in the fabrication process.

As used herein the term “doping” is intended to refer to the introduction of impurity elements into material to give the material desired properties.

In one embodiment, as used herein “doping” can be performed by methods that can include but are not limited to diffusion and ion implantation.

In one embodiment, as used herein the term “backside” is intended to refer to a backside of a solar cell that is opposite to the front side of the solar cell, wherein the front side of the solar cell faces the sun during normal operation. In one embodiment, as used herein the term “backside contact solar cell” is intended to refer to a solar cell where all electrical connections to its collection regions are formed on its backside. In one embodiment, in a backside contact solar cell, both doped regions and interdigitated metal contact fingers coupled to them, are located on the backside of the solar cell. In one embodiment, the contact fingers allow an external electrical circuit to be coupled to and powered by the solar cell.

In one embodiment, the term “non-contiguous” polysilicon is intended to refer to non-continuous and separated portions of polysilicon. In particular, to a plurality of non-continuous and separated (by surrounding trenches) polysilicon islands having a bounded periphery that can include various shapes.

Solar cells convert solar radiation to electrical energy. A solar cell typically includes p-type and n-type doped regions. Solar radiation impinging the surface of the solar cell creates electrons and holes that diffuse to the doped regions and cause voltage differentials to develop between the doped regions. In a backside contact solar cell, the doped regions and metal contacts that are coupled to them are located on the backside of the solar cell. The metal contacts allow an external electrical circuit to be coupled to and powered by the solar cell.

Solar cell efficiency is an important operational characteristic of solar cells as solar cell efficiency is directly related to its capacity to generate power. Carrier recombination is a significant factor in the determination of solar cell efficiency because carriers that recombine may not provide a net contribution to the current that is produced by a solar cell.

Passivating contacts are charge carrier selective contacts that are used in silicon based solar cells. Two types of passivating contacts are n and p type polycrystalline silicon on SiOx passivating contacts. n and p type polycrystalline silicon on SiOₓ passivating contacts are respectively, electron, and hole selective, high-efficiency contacts. The use of these types of passivating contacts in interdigitated back contact (IBC) solar cells can be challenging due to the need to isolate n and p type polysilicon layers from each other. Moreover, due to the poorer surface passivation performance of p-type polysilicon with respect to that of n-type polysilicon, it is important that the patterning technique used in the fabrication of the polysilicon contacts enables precise control over the p-type polysilicon coverage area fraction, such that precise optimization of that coverage area fraction for maximal solar cell efficiency can be achieved (by limiting the coverage area fraction of the poorer performing p-type polysilicon). At lab scale, this challenge can be readily addressed by the use of effective but expensive patterning techniques, such as photolithography. However, in manufacturing, such techniques can be cost prohibitive.

A method for forming a solar cell is disclosed herein that addresses the aforementioned challenges. In one embodiment, the method for forming a solar cell includes forming a multilayered stack of materials on a substrate, forming a plurality of openings in the top layer of the multilayered stack of materials, forming a plurality of dielectric regions that are aligned to the plurality of openings on a polysilicon layer of the multilayered stack of materials, and forming a plurality of trenches around the plurality of dielectric regions to form a plurality of first polysilicon regions and one or more second polysilicon regions. The method further includes, after forming the plurality of trenches, forming a first doped material on exposed surfaces of remaining portions of the multilayered stack of materials, using the first doped material to cause the plurality of first polysilicon regions to have a doping type that corresponds to the doping type of the first doped material, and using a second doped material to cause the one or more second polysilicon regions to have a doping type that corresponds to the doping type of the second doped material.

Control of contact area fraction of the hole-selective layer of polysilicon in a solar cell (such as is done using the aforementioned method) is enabled by the self-alignment methods described herein. In one embodiment, due to the poorer surface passivation performance of p-type polysilicon (as regards carrier recombination) as compared to that of n-type polysilicon, the p-type polysilicon coverage area fraction is precisely tuned, using the herein described self-alignment processes, to provide a coverage area fraction that delivers maximal solar cell efficiency (by limiting the contact area fraction of the poorer performing p-type polysilicon). Thus, the solar cell is designed in a manner that limits opportunities for carrier recombination. In one embodiment, the limiting of opportunities for carrier recombination can have a favorable effect on the net contribution of carriers to the current that is produced by the solar cell and on solar cell efficiency.

### Solar Cell

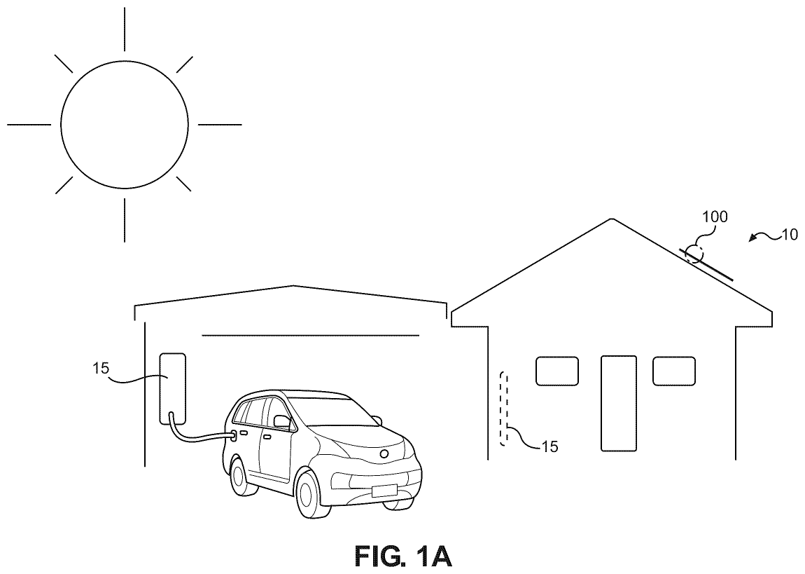

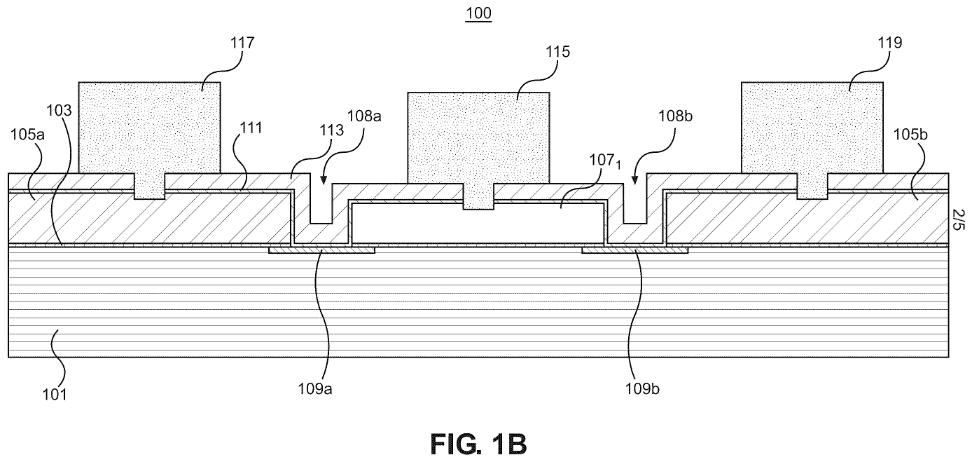

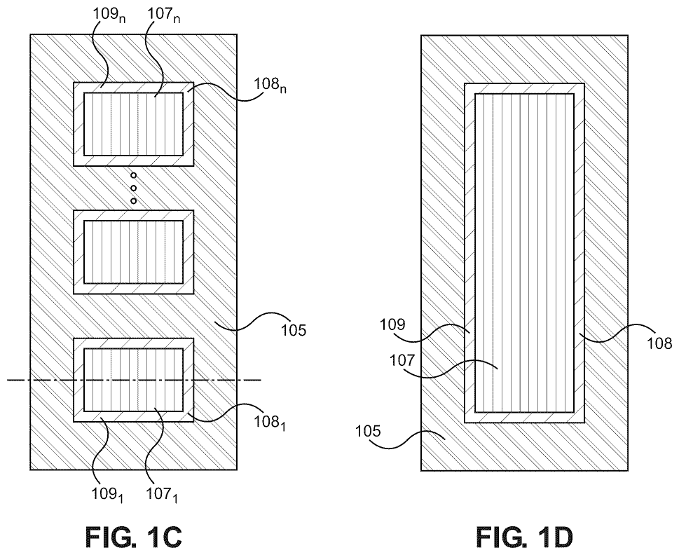

FIG. 1A illustrates an exemplary operating environment of photovoltaic modules having solar cells whose passivating contacts have a controlled coverage area fraction according to one embodiment. FIG. 1A shows a house that has photovoltaic modules 10 that include solar cells 100 (hereinafter “the solar cells” or “a solar cell” or “the solar cell”) that are installed on its roof. In one embodiment, the photovoltaic modules 10 utilize the electrical energy generated by the solar cells 100 to supply the house with electricity (e.g., to power appliances 15). It should be noted that the depicted residential operating environment is only exemplary and that embodiments are equally useful in many other types of operating environments such as commercial.

FIG. 1B shows a cross-section of a portion of the solar cell 100 according to one embodiment. In one embodiment, the solar cell 100 includes wafer 101, passivating dielectric 103, n-doped polysilicon region 105a, n-doped polysilicon region 105b, p-doped polysilicon layer 1071, trench 108a, trench 108b, doped region 109a, doped region 109b, dielectric layer 111, dielectric layer 113, conductor layer 115, conductor layer 117 and conductor layer 119.

Referring to FIG. 1B, the wafer 101 forms the substrate upon which the semiconductor, dielectric and conductor layers of the solar cell 100 are formed. In one embodiment, the passivating dielectric 103 is formed on the surface of the wafer 101 and includes spaces through which the doped regions 109a and 109b are formed, and in which the dielectric layer 111 is formed. In one embodiment, the passivating dielectric 103 can be uniform. In other embodiments, the passivating dielectric 103 can have different thicknesses and/or different compositions (e.g., in places where n and p-doped polysilicon material interfaces with the passivating dielectric 103). In one embodiment, there can be diffusions of n and p-type dopants onto the wafer 101 surface (not shown) at places where n and p-doped polysilicon interfaces with wafer 101. In one embodiment, the p-doped polysilicon layer 1071 is formed on a portion of the wafer 101 between laterally situated n-doped polysilicon region 105a and n-doped polysilicon region 105b. In one embodiment, the p-doped polysilicon layer 107₁ includes sides that are covered by the dielectric layer 111 and a top surface that is partially covered by the dielectric layer 111. In addition, in one embodiment, the p-doped polysilicon layer 107₁ is contacted on its top surface through a space in the dielectric layer 111 by conductor layer 115. In one embodiment, the n-doped polysilicon regions 105a and 105b are formed on the surface of the passivating dielectric 103 and are separated from the p-doped polysilicon layer 107₁ by portions of the dielectric layer 111 that extend into the space that surrounds the p-doped polysilicon layer 107₁. In one embodiment, the doped region 109a is formed in the wafer 101 below a portion of the dielectric layer 111 that extends into a first space in the passivating dielectric 103. In addition, in one embodiment, the doped region 109a laterally extends underneath a portion of the passivating dielectric 103 that is formed underneath the p-doped polysilicon layer 107₁ and a portion of the passivating dielectric 103 that is formed underneath the n-doped polysilicon region 105a. In one embodiment, the doped region 109b is formed in the wafer 101 below a portion of the dielectric layer 111 that extends into a second space in the passivating dielectric 103. In addition, in one embodiment, the doped region 109b laterally extends underneath a portion of the passivating dielectric 103 that is formed underneath the p-doped polysilicon layer 107₁ and a portion of the passivating dielectric 103 that is formed underneath the n-doped polysilicon region 105b. In one embodiment, the dielectric layer 111 extends along the top and inner side surface of the n-doped polysilicon region 105a, on the surface of the wafer 101 between the n-doped polysilicon region 105a and the p-doped polysilicon layer 107₁, along the top and side surfaces of the p-doped polysilicon layer 107₁, on the surface of the wafer 101 between the p-doped polysilicon layer 107₁ and the n-doped polysilicon region 105b, and along the top and inner side surface of the n-doped polysilicon region 105b. In one embodiment, the dielectric layer 113 covers and extends along the entire the top surface of the dielectric layer 111. In one embodiment, the dielectric layer 111 and the dielectric layer 113 include openings above the p-doped polysilicon layer 107₁, the n-doped polysilicon region 105a, and the n-doped polysilicon region 105b that enable the p-doped polysilicon layer 107₁, the n-doped polysilicon region 105a and the n-doped polysilicon region 105b to be contacted by the conductor layer 115, the conductor layer 117 and the conductor layer 119 respectively. In one embodiment, trenches 108a and 108b are opposite side cross-sectional parts of a trench (e.g., trench 108₁ described with reference to FIG. 1C) that surrounds the p-doped polysilicon layer 107₁.

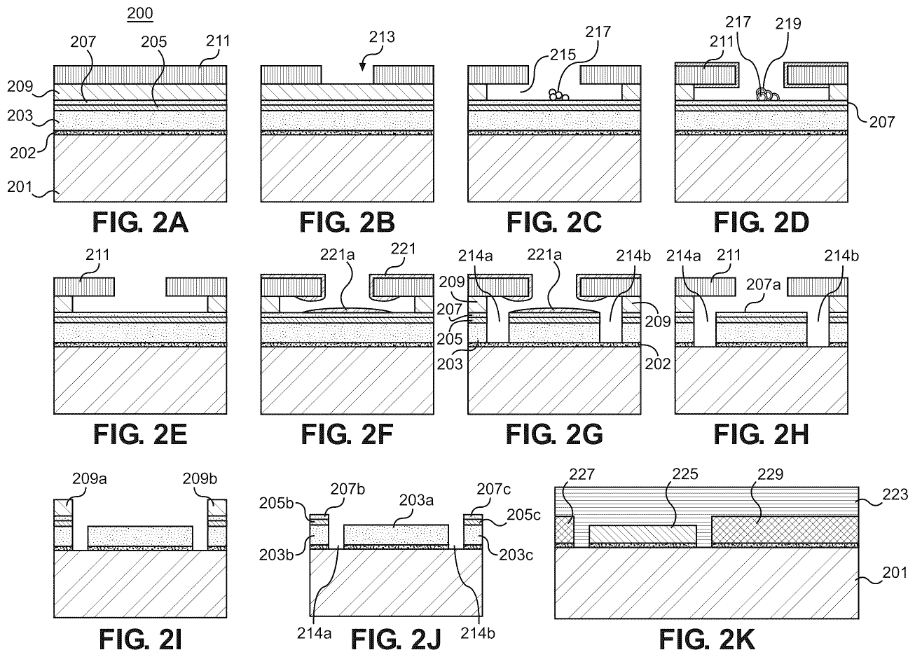

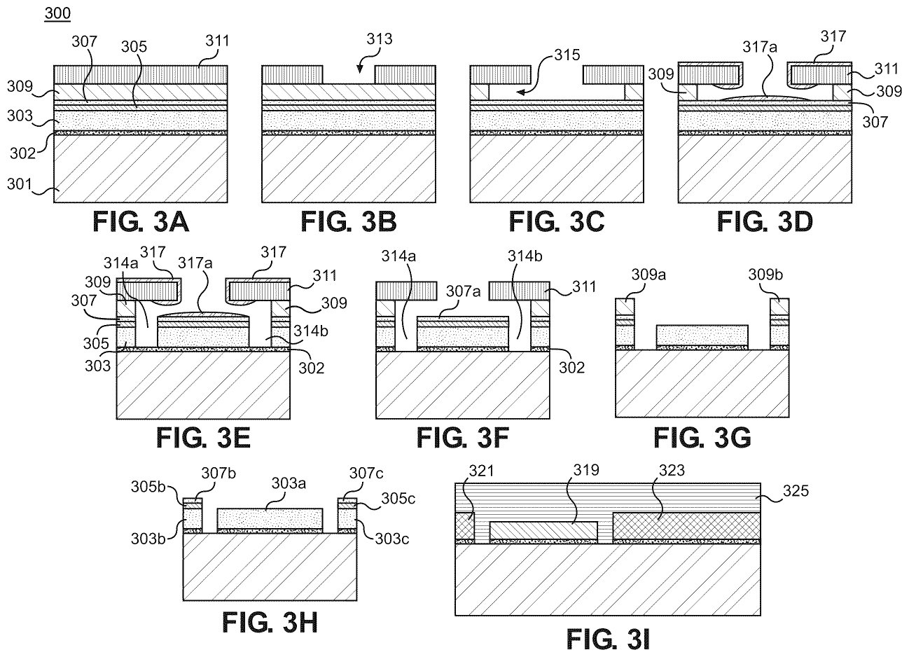

Referring to FIG. 1C, in one embodiment, the trenches 108a and 108b, shown in FIG. 1B, are opposite side cross-sectional parts of a trench 108₁ that is formed around the p-doped polysilicon layer 107₁. Moreover, in one embodiment, the trench 108₁ is one of a plurality of trenches 108₁-108ₙ formed around a plurality of polysilicon islands 107₁-107ₙ in solar cell 100 (see FIG. 1C). In one embodiment, the trenches can have shapes that can include but are not limited to circular, rectangular, elongated, elliptical, polygonal and irregular. In one embodiment, the polysilicon islands 107₁-107ₙ have a coverage area fraction of 5 to 80 percent. In one embodiment, the trenches 108₁-108ₙ are formed using a self-aligned process that is described herein with reference to FIGS. 2A-2K and 3A-3I. In one embodiment, self-alignment enables the formation of a narrower trench than can be obtained by some other conventional processes. In one embodiment, self-alignment enables the formation of trenches having widths of 1 micron or less. In addition, in one embodiment, the portion of unetched trench that is allowed is equal to or less than a 0.1 percent fraction of the perimeter length.

FIG. 1D shows an embodiment that includes a single elongated polysilicon island 107 that is surrounded by a trench 108 (also shown is doped region 109 and n-doped polysilicon region 105). In other embodiments a combination of the respective embodiments shown in FIG. 1C and FIG. 1D can be used.

In one embodiment, the polysilicon islands 107₁-107ₙ are a plurality of non-contiguous doped polysilicon regions of p-type conductivity that are formed in lasered regions of the semiconductor structure (see FIGS. 2A-2K). In other embodiments, the polysilicon islands 107₁-107ₙ are a plurality of non-contiguous doped polysilicon regions of p-type conductivity that are formed in non-lasered regions of the semiconductor structure and (see FIGS. 3A-3I).

In one embodiment, the wafer 101 can be formed from silicon. In other embodiments, the wafer 101 can be formed from other materials. In one embodiment, the passivating dielectric 103 can be formed from silicon oxide. In other embodiments, the passivating dielectric 103 can be formed from other materials. In one embodiment, the n-doped polysilicon regions 105a and 105b can be doped with phosphorous. In other embodiments, the n-doped polysilicon regions 105a and 105b can be doped with other impurities. In one embodiment, the p-doped polysilicon layer 107₁ can be doped with boron. In other embodiments, the p-doped polysilicon layer 107₁ can be doped with other impurities. In one embodiment, the doped regions 109a and 109b can be doped with boron. In other embodiments, the doped regions 109a and 109b can be doped with other materials. In one embodiment, the dielectric layer 111 can include aluminum oxide. In other embodiments, dielectric layer 111 can include other materials. In one embodiment, the dielectric layer 113 can include silicon nitride. In other embodiments, the dielectric layer 113 can include other materials. In one embodiment, the conductor layer 115 can include aluminum, nickel, chromium, gold, germanium, copper, silver, titanium, tungsten, tin, platinum, and tantalum. In other embodiments, the conductor layer 115 can include other materials. In one embodiment, the conductor layer 117 can include aluminum, nickel, chromium, gold, germanium, copper, silver, titanium, tungsten, tin, platinum, and tantalum. In other embodiments, the conductor layer 117 can include other materials. In one embodiment, the conductor layer 119 can include aluminum, nickel, chromium, gold, germanium, copper, silver, titanium, tungsten, tin, platinum, and tantalum. In other embodiments, the conductor layer 119 can include other materials.

### Operation

In operation, upon exposure to light, the solar cell 100 converts light energy into electricity based on the photovoltaic effect. Some carriers reach the p-n junction and contribute to the current produced by the solar cell 100. However, other carriers recombine with no net contribution to the current produced by the solar cell 100. Carrier recombination is a significant factor in the determination of solar cell efficiency. In one embodiment, due to the poorer surface passivation performance of p-type polysilicon (as regards carrier recombination) as compared to that of n-type polysilicon, the p-type polysilicon coverage area fraction is precisely tuned to provide a coverage area fraction that delivers maximal solar cell efficiency (by limiting the contact area fraction of the poorer performing p-type polysilicon). Thus, the solar cell 100 is designed in a manner that limits the opportunities for carrier recombination that may be available with conventional solar cells. In one embodiment, the limiting of opportunities for carrier recombination has a favorable effect on carrier recombination and solar cell efficiency.

### Solar Cell Fabrication Process

FIGS. 2A-2K are illustrations of cross-sections of a multilayered semiconductor structure 200 during fabrication of a solar cell whose passivating contacts have a controlled coverage area fraction according to one embodiment. Referring to 2A, a cross-section of the multilayered semiconductor structure 200 is shown after initial operations that include forming a multilayered stack of semiconductors and dielectrics above a wafer. In one embodiment, the semiconductor structure 200 includes wafer 201, passivating dielectric 202, intrinsic polysilicon layer 203, n-type polysilicon layer 205, intrinsic polysilicon layer 207, dielectric layer 209, and amorphous silicon (a-Si) layer 211. In one embodiment, the a-Si layer 211 can be replaced with non-amorphous silicon. In one embodiment, the polysilicon layer 203, 205, and 207 can be replaced with non-polycrystalline silicon. In one embodiment, the dielectric layer 209 can include silicon oxide (SiOx). In other embodiments, the dielectric layer 209 can include a dielectric material other than silicon oxide. In one embodiment, the dielectric layer 209 can have a thickness of 60 nm. In other embodiments, the dielectric layer 209 can have other thicknesses. In one embodiment, the a-Si layer 211 can have a thickness of 28 nm. In other embodiments, the a-Si layer 211 can have other thicknesses.

Referring to FIG. 2B, after operations that result in the cross-section shown in FIG. 2A, laser ablation is performed on the a-Si layer 211. In one embodiment, the laser ablation operation removes portions of the a-Si layer 211 to form a plurality of openings 213 in the a-Si layer 211. Unlike other scalable cost-effective techniques, such as ink printing, laser ablation imposes no lower limit on coverage area fraction. In other embodiments, other manners of forming the openings in the a-Si layer 211 can be used.

In one embodiment, the pulses used in the laser operations can have a gaussian-shaped pulse profile, or a beam profile that is nearly flat top or flat-top like, characterized by non-abrupt change in intensity from the high-intensity beam center to a zero-intensity outside-of-pulse region. In other embodiments, laser operations can include other type pulse and beam profiles.

Referring to FIG. 2C, after one or more operations resulting in the cross-section shown in FIG. 2B, a dielectric etch is performed. In one embodiment, a hydrofluoric acid (HF) etch is performed. In other embodiments, other types of etches can be performed. In one embodiment, the etch is used to remove portions of the dielectric layer 209. In one embodiment, the dielectric etch can result in the formation of a defect precursor 217, for example, silicon particles, on the exposed surface of the intrinsic polysilicon layer 207.

Referring to FIG. 2D, after one or more operations resulting in the cross-section shown in FIG. 2C, a DIO₃ operation is performed that results in the formation of dielectric material 219 on exposed surfaces of the a-Si layer 211 and on the defect precursor 217 that is formed on the surface of the intrinsic polysilicon layer 207 (defect precursor 217 shown in FIG. 2C). In one embodiment, the dielectric material 219 formed on exposed surfaces of the a-Si layer 211 and on the defect precursor 217 formed on the surface of the intrinsic polysilicon layer 207 can be SiOx.

Referring to FIG. 2E, after one or more operations resulting in the cross-section shown in FIG. 2D, an hydrofluoric acid (HF) liftoff operation is performed. As part of the HF liftoff operation, the dielectric material 219 that is formed on exposed surfaces of the a-Si layer 211 and the defect precursor (including the dielectric material 219 that is formed thereon) that is formed on the surface of the intrinsic polysilicon layer 207, are removed.

Referring to FIG. 2F, after one or more operations resulting in the cross-section shown in FIG. 2E, dielectric material 221 is formed on the top surface of the aSi layer 211, on the sidewalls of the opening in the aSi layer 211, on portions of the bottom surface of the aSi layer 211 that are adjacent the opening in the aSi layer 211 (in the undercut region lying below the bottom surface of the aSi layer 211), and on a center portion of the surface of the intrinsic polysilicon layer 207 (labelled 221a). In one embodiment, the dielectric material 221 can include SiNx. In other embodiments, the dielectric material 221 can include other materials. In one embodiment, the dielectric material 221a that is formed on the center portion of the surface of the intrinsic polysilicon layer 207 acts as etch resist that is used to form trenches or moats by etching away material from a plurality of layers that includes the intrinsic polysilicon layer 203, the n-type polysilicon layer 205, and the intrinsic polysilicon layer 207 (as in FIG. 2G).

In one embodiment, to prepare the semiconductor structure 200 for the formation of trenches, the dielectric material 221a that is formed on the center portion of the surface of the intrinsic polysilicon layer 207 can be formed to have a perimeter that extends laterally beyond the perimeter of the a-Si openings 213. In one embodiment, in subsequent operations, the lateral extent of the etching of the polysilicon away from the perimeter of the dielectric material 221a determines the position of the outer sidewalls of the trenches.

Referring to FIG. 2G, after one or more operations resulting in the cross section shown in FIG. 2F, a potassium hydroxide (KOH) etch is performed. In particular, in one embodiment, the KOH etch is used to remove portions of the polysilicon layers 203, 205 and 207 that surround the perimeters of the dielectric material 221a. In one embodiment, the dielectric material 221a formed on the surface of the polysilicon layer 207 acts as an etch resist against the potassium hydroxide (KOH) that is used in the etching process. The result is a plurality of, dielectric material 221a, covered polysilicon islands, formed in the polysilicon layers 203, 205 and 207, that are surrounded by a plurality of trenches (see FIG. 1C). Referring to FIG. 2G, trench sections 214a and 214b are opposite side cross-sectional regions of a trench or moat that surrounds the polysilicon island associated with the dielectric material 221a.

In one embodiment, the trenches are etched in the regions of the polysilicon layers 203, 205 and 207 that lie between the perimeters of the dielectric material 221a and the inner edge of the laterally etched dielectric layer 209. In one embodiment, the regions of the polysilicon layers 203, 205 and 207 that lie between the perimeters of the dielectric material 221a and the inner edge of the laterally etched dielectric layer 209 can have shapes that include but are not limited to circular, elliptical, elongated, rectangular and irregular.

Referring to FIG. 2H, after one or more operations resulting in the cross-section shown in FIG. 2G, an HF etch is performed. In one embodiment, the HF etch removes the dielectric material 221 from the top surface of the aSi layer, the sidewalls of the opening in the aSi layer, and portions of the bottom surface of the aSi layer adjacent the opening in the aSi layer (in the undercut region lying below the bottom surface of the aSi layer), and dielectric material 221a from the surface of the polysilicon layer 207a and portions of the passivating dielectric 202 that is located at the bottom of the trenches 214a and 214b.

Referring to FIG. 2I, after one or more operations resulting in the cross-section shown in FIG. 2H, a KOH etch is performed. In one embodiment, the KOH etch removes the remaining portions of the aSi layer 211, and the portions of the polysilicon layers 207, 205 at the island previously covered by layer 221a. In addition, in other embodiments, the KOH etch also partially removes the polysilicon layer 203 previously covered by layer 221a.

Referring to FIG. 2J, after one or more operations resulting in the cross-section shown in FIG. 2I, an HF etch is performed. In one embodiment, the HF etch removes the remaining portions of the dielectric layer 209 (e.g., 209a and 209b).

Referring to FIG. 2K, after one or more operations resulting in the cross-section shown in FIG. 2J, p-doped dielectric material 223 is formed on the exposed surfaces of the semiconductor structure 200. Subsequently, in one embodiment, thermal drive operations are performed to cause p-type dopants to diffuse out of the p-doped dielectric material 223 into the polysilicon islands 203a. In one embodiment (which is not shown in FIGS. 2A-2K), the thermal drive process causes p-type dopants to diffuse out of the p-doped dielectric material 223 into areas of the wafer 201 that are located under and around the bottom of the trenches 214a and 214b. In one embodiment, this diffusion of p-type dopant produces p+diffused regions in areas of the wafer 201 located under and around the bottom of the trenches 214a and 214b (not shown). In addition, in one embodiment, p- and n-type dopants from polysilicon 225, and, 227 and 229, respectively, also diffuse into areas of the wafer 201 that are located under and around the bottom of polysilicon 225, and, 227 and 229 (not shown).

In one embodiment, the portions, 205b and 205c, of the n-type polysilicon layer 205 that remain after the operations described with reference to FIGS. 2A-2J are completed, are used in the thermal drive operations as the dopant sources for the n-type doping of the remaining portions, 203b and 203c, and 207b and 207c, of the polysilicon layers 203 and 207. In one embodiment, the p-doped dielectric material 223 can include SiOx. In other embodiments, dielectric materials other than SiOx can be used.

Referring again to FIG. 2K, after the thermal operations are completed, n-type passivating contact 227, n-type passivating contact 229 and p-type passivating contact 225 are formed. It should be noted that n-type passivating contact 227 and n-type passivating contact 229 are cross-sectional parts of a single passivating contact that surrounds p-type passivating contact 225 (see FIG. 1C n-type passivating contact 105 surrounding p-type passivating contact 1071).

In one embodiment, the operations described with reference to FIG. 2C and FIG. 2D can be replaced by other techniques such as: (1) an HFO₃ clean, (2) sonication in DIO₃, or (3) other wet chemistries that promote oxidation of Si. It should be noted that for purposes of clarity and brevity possible dopant diffusion onto the wafer surface and formation of an SiOx interfacial film between the wafer 201 and the intrinsic polysilicon layer 203 is not shown.

In one embodiment, the self-aligned process for forming the passivating contacts that is described with reference to FIGS. 2A-2K provides solar cells that feature maximized passivation and charge-carrier collection achieved by precise control of p-type polysilicon coverage area fraction. Another self-aligned process for controlling coverage area fraction of p-type polysilicon is described with reference to FIGS. 3A-3I.

FIGS. 3A-3I are illustrations of cross-sections of a multilayered semiconductor structure 300 during fabrication of a solar cell according to one embodiment. Referring to FIG. 3A, a cross-section of the multilayered semiconductor structure 300 is shown after initial operations that include forming a multilayered stack of semiconductors and other material above a wafer.

In one embodiment, the semiconductor structure 300 includes wafer 301, passivating dielectric 302, intrinsic polysilicon 303, n-type polysilicon layer 305, intrinsic polysilicon layer 307, sacrificial layer 309, and sacrificial layer 311. In one embodiment, the sacrificial layer 309 can include any suitable sacrificial material. In one embodiment, the sacrificial layer 311 can include any suitable sacrificial material. In one embodiment, the sacrificial layer 309 can have a thickness of 60 nm. In other embodiments, the sacrificial layer 309 can have other thicknesses. In one embodiment, the sacrificial layer 311 can have a thickness of 28 nm. In other embodiments, the sacrificial layer 311 can have other thicknesses.

Referring to FIG. 3B, after operations that result in the cross-section shown in FIG. 3A, patterning operations are performed on the sacrificial layer 311. In one embodiment, the patterning operations result in the removal of portions of the sacrificial layer 311 to form a plurality of openings 313 in the sacrificial layer 311 In one embodiment, any suitable manner of patterning and forming the plurality of openings can be used.

Referring to FIG. 3C, after one or more operations resulting in the cross-section shown in FIG. 3B, a selective etch is performed. In particular, in one embodiment, the selective etch is used to remove portions of the sacrificial layer 309.

Referring to FIG. 3D, after one or more operations resulting in the cross-section shown in FIG. 3C, sacrificial material 317 is formed on the top surface of the sacrificial layer 311, on the sidewalls of the opening in the sacrificial layer 311, on portions of the bottom surface of the sacrificial layer 311 that are adjacent the opening in the sacrificial layer 311 (in the undercut region lying below the bottom surface of the sacrificial layer 311), and on a center portion of the surface of the intrinsic polysilicon layer 307 (e.g., 317a). In one embodiment, the sacrificial material 317 can be formed using any suitable material for forming the sacrificial material 317. In one embodiment, the sacrificial material 317a that is formed on the center portion of the surface of the intrinsic polysilicon layer 307 acts as an etch resist that is used to form trenches or moats in the stack of layers that includes the intrinsic polysilicon layer 303, the n-type polysilicon layer 305, and the intrinsic polysilicon layer 307.

In one embodiment, to prepare the semiconductor structure 300 for the formation of trenches, the sacrificial material 317a that is formed on the center portion of the surface of the intrinsic polysilicon layer 307 can be formed to have a perimeter that extends laterally beyond the perimeter of the openings 313. In one embodiment, in subsequent operations, the lateral extent of the etching of the polysilicon away from the perimeter of the sacrificial material 317a determines the position of the outer sidewalls of the trenches.

Referring to FIG. 3E, after one or more operations resulting in the cross section shown in FIG. 3D, a selective etch is performed. In one embodiment, the selective etch is used to remove portions of the polysilicon layers 303, 305 and 307 that surround the perimeters of the sacrificial material 317a. In one embodiment, the sacrificial material 317a formed on the surface of the polysilicon layer 307 acts as etch resist. The result of the selective etch is the formation of a plurality of sacrificial material 317a, covered, polysilicon islands, formed in the polysilicon layers 303, 305 and 307, that are surrounded by a plurality of trenches (see FIG. IC). Referring to FIG. 3E, trench cross-sections 314a and 314b are opposite side cross-sectional regions of a trench or moat that surrounds the polysilicon island associated with the sacrificial material 317a.

In one embodiment, the trenches are etched in the regions of the polysilicon layers 303, 305 and 307 that lie between the perimeters of the sacrificial material 317a and the inner edge of the laterally etched sacrificial layer 309. In one embodiment, the regions of the polysilicon layers 303, 305 and 307 that lie between the perimeters of the sacrificial material 317a and the inner edge of the laterally etched sacrificial layer 309 can have shapes that include but are not limited to circular, elliptical, elongated, rectangular and irregular. In one embodiment, the trenches can have sharp sidewall angles of 90 degrees or less steep on both sides. In one embodiment, the inner sidewall angle can be more shallow than the outer sidewall angle.

Referring to FIG. 3F, after one or more operations resulting in the cross-section shown in FIG. 3E, a selective etch is performed. In one embodiment, the selective etch removes the sacrificial material 317 from the top surface of the sacrificial layer 311, the sidewalls of the opening in the sacrificial layer 311, and portions of the bottom surface of the sacrificial layer 311 adjacent the opening in the sacrificial layer 311 (in the undercut region lying below the bottom surface of the sacrificial layer 311), and the sacrificial material 317a from the surface of the polysilicon layer 307a and the passivating dielectric 302 from the bottom of trenches 314a and 314b.

Referring to FIG. 3G, after one or more operations resulting in the cross-section shown in FIG. 3F, a selective etch is performed. In one embodiment, the selective etch removes the remaining portions of the sacrificial layer 311, as well as portions of polysilicon layers 305 and 307 that were previously covered by layer 317a. In other embodiments, the selective etch also partially removes layer 303 that was previously covered by layer 307a. In one embodiment, the removal of the portions of polysilicon layers 305 and 307 that were above the polysilicon island portions of polysilicon layer 303 enables a subsequent doping of the islands (p-type).

Referring to FIG. 3H, after one or more operations resulting in the cross-section shown in FIG. 3G, a selective etch is performed. In one embodiment, the selective etch removes the remaining portions of the sacrificial layer 309 (e.g., 309a and 309b).

Referring to FIG. 3I, after one or more operations resulting in the cross-section shown in FIG. 3H, cleaning, doping, and thermal drive operations are performed. In one embodiment, any suitable manner of performing the cleaning, doping and thermal drive operations can be used. Referring again to FIG. 3I, after the cleaning, doping, and thermal drive operations are completed, n-type passivating contact 321, n-type passivating contact 323 and p-type passivating contact 319 are formed. The removal of silicon layers (FIG. 3G) in the formation passivating contact 319, and the usage of a plurality of polysilicon layers (FIGS. 3H and 3I) in the formation of passivating contacts 321 and 323, results in a thickness difference between the n and the p-type passivating contacts. More specifically, the passivating contacts 321 and 323 are caused to be much thicker than the passivating contact 319.

It should be appreciated that in one embodiment, after the cleaning doping and thermal drive operations are performed, a film 325 (similar to p-doped dielectric material 223 in FIG. 2K that is used as a source of dopant in the processes described with reference to FIGS. 2A-2K) can remain as part of the semiconductor structure and ultimately the solar cell that is fabricated. However, in other embodiments, the film 325 may not remain, and may be removed after its use as a dopant source. In still other embodiments, instead of using a film such as film 325, ion implantation can be used as a doping mechanism or source of dopants.

It should be appreciated that some of the processing operations discussed with reference to FIGS. 3A-3I can be performed in manners different from those described with reference to FIGS. 2A-2K. For example: (1) patterning can be performed by techniques other than laser, such as photolithography or other masked etch techniques; and (2) the sacrificial material described with respect to FIGS. 2F and 3D can be formed from chemically grown oxide.

In one embodiment, the self-aligned process for forming the passivating contacts that is described with reference to FIGS. 3A-3I provides maximum optimization of passivation and charge-carrier collection by precisely controlling p-type polysilicon coverage area fraction and minimizing the trench width.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

The various features of different embodiments may be variously combined with some features included and others excluded to suit a variety of different applications.

What is claimed is:

1. A method of forming a solar cell, comprising:
forming a multilayered stack of materials on a substrate;
forming a plurality of openings in the top layer of the multilayered stack of materials;
forming a plurality of dielectric regions, that are aligned to the plurality of openings, on a polysilicon layer of the multilayered stack of materials;
forming a plurality of trenches around the plurality of dielectric regions to form a plurality of first polysilicon regions and one or more second polysilicon regions;
after forming the plurality of trenches, forming a first doped material on exposed surfaces of remaining portions of the multilayered stack of materials;
using the first doped material to cause the plurality of first polysilicon regions to have a doping type that corresponds to the doping type of the first doped material;
and
using a second doped material to cause the one or more second polysilicon regions to have a doping type that corresponds to the doping type of the second doped material.

2. The method of claim 1, wherein the plurality of dielectric regions have perimeters that extend laterally beyond the perimeters of the plurality of openings.

3. The method of claim 1, wherein the plurality of dielectric regions have perimeters that do not extend laterally beyond the perimeters of the plurality of openings.

4. The method of claim 1, further comprising: before forming the plurality of dielectric regions, laterally etching a layer of dielectric material to a position beyond a determined perimeter of the plurality of dielectric regions.

5. The method of claim 4, further comprising:
after laterally etching the layer of dielectric material, forming other dielectric material on exposed surfaces of the top layer of the multilayered stack of materials and on defect precursors; and
removing the other dielectric material including the defect precursors.

6. The method of claim 1, wherein the second doped material is derived from a layer of the multilayered stack of material.

7. The method of claim 1, wherein the first doped material is a dielectric, and the second doped material is doped silicon.

8. The method of claim 1, wherein a thermal process is executed to cause the plurality of first polysilicon regions to have doping that corresponds to the doping of the first doped material, and the one or more second polysilicon regions to have doping that corresponds to the doping of the second doped material.

9. The method of claim 1, wherein the openings are formed using a laser.

10. The method of claim 1, wherein the first doped material is doped silicon oxide.

11. The method of claim 1, wherein the top layer of the multilayered stack of materials is amorphous silicon.

12. A method of forming a solar cell, comprising:
forming a multilayered stack of materials on a substrate;
forming a plurality of openings in a first sacrificial layer of the multilayered stack of materials;
forming a plurality of regions of sacrificial material, that are aligned to the plurality of openings, on a silicon layer of the multilayered stack of materials;
forming a plurality of trenches around the plurality of regions of sacrificial material to form a plurality of first polysilicon regions and one or more second polysilicon regions;
causing the plurality of first polysilicon regions to have doping that corresponds to a first doped material; and
using a second doped material to cause the one or more second polysilicon regions to have doping that corresponds to the doping of the second doped material.

13. The method of claim 12, wherein the plurality of regions of sacrificial material have perimeters that extend laterally beyond the perimeters of the plurality of openings.

14. The method of claim 12, wherein the plurality of regions of sacrificial material have perimeters that do not extend laterally beyond the perimeters of the plurality of openings.

15. The method of claim 12, further comprising: before forming the plurality of regions of sacrificial material, laterally etching a second sacrificial layer of the multilayered stack of materials to a position beyond a determined perimeter of the plurality of regions of sacrificial material.

16. The method of claim 12, wherein the second doped material is derived from a layer of the multilayered stack of material.

17. The method of claim 12, wherein the first doped material is implanted dopants, and the second doped material is polysilicon.

18. The method of claim 12, wherein a thermal process is executed to cause the one or more second polysilicon regions to have doping that corresponds to the doping of the second doped material.

19. The method of claim 12, wherein the first sacrificial layer of the multilayered stack of materials is amorphous silicon.

20. A solar cell, comprising:
a substrate;
a dielectric layer on a backside of the substrate;
a plurality of non-contiguous first passivating contact regions having a first polarity on the dielectric layer, that have a coverage area fraction that is between 5 and 80 percent; and at least one second passivating contact region having a second polarity on the dielectric layer, laterally disposed to the plurality of non-contiguous passivating contact regions.

21. The solar cell of claim 20, wherein the plurality of non-contiguous first passivating contact regions include precursor removed surface profiles.
